(19) United States
(12) Patent Application Publication
(10) Pub. No.: US 2009/0108385 A1
(43) Pub. Date: Apr. 30, 2009

(54) METHOD AND APPARATUS FOR IMPROVING CROSSTALK AND SENSITIVITY IN AN IMAGER

(75) Inventors: Thomas Edward Dungan, Fort Collins, CO (US); Christopher Silsby, Albany, OR (US); Chintamani Prabhakar Palsule, Fort Collins, CO (US)

Correspondence Address: RatnerPrestia, P.O. BOX 980, VALLEY FORGE, PA, 19482, US

(73) Assignee: Micron Technology, Inc., Boise, ID (US)

(21) Appl. No.: 11/926,687

(22) Filed: Oct. 29, 2007

(51) Int. Cl. H01L 31/0232; H01L 31/103

(52) U.S. Cl. 257/432; 257/440; 257/E31.128; 257/E31.057

(57) ABSTRACT

A pixel sensor cell includes a substrate of a first conductivity type, and a photoconversion region. The photoconversion region includes a pinning layer of the first conductivity type for receiving incident light of multiple colors, and a diode implant layer of a second conductivity type, disposed below the pinning layer, for accumulating photo-generated charge. Also included is a deep well of the first conductivity type, disposed below the diode implant layer, for rejecting at least one color of the incident light. The deep well includes a doped region, vertically disposed at a predetermined depth below the diode implant layer. The diode implant layer is effective in accumulating photo-generated charge of a blue color, and the deep well is effective in rejecting photo-generated charges of green and red colors from the diode implant layer. By placing the deep well at another predetermined depth below the diode implant layer, the deep well is effective in rejecting photo-generated charge of a red color from the diode implant layer.

### FIELD OF THE INVENTION

Embodiments of the invention relates generally to methods and apparatus pertaining to a pixel array of an imager. In particular, embodiments of the invention relate to improving crosstalk and sensitivity of the imager.

### BACKGROUND OF THE INVENTION

Typically, a digital imager array includes a focal plane array of pixel cells, each one of the cells including a photoconversion device, e.g. a photogate, photoconductor, or a photodiode. In one such imager, known as a CMOS imager, a readout circuit is connected to each pixel cell which typically includes a source follower output transistor. The photoconversion device converts photons to electrons which are typically transferred to a charge storage region, which may be a floating diffusion region, connected to the gate of the source follower output transistor. A charge transfer device (e.g., transistor) can be included for transferring charge from the photoconversion device to the floating diffusion region. In addition, such imager cells typically have a transistor for resetting the floating diffusion region to a predetermined charge level prior to charge transference. The output of the source follower transistor may be gated as an output signal by a row select transistor.

FIG. 1 illustrates a block diagram of imager device 308 having pixel array 200 with each pixel cell being constructed as described above. Pixel array 200 includes an array of pixels arranged in a predetermined number of columns and rows. The pixels of each row in array 200 transfer their signal charge to the output columns when selected by a signal on one of the horizontal control lines, and the pixels of each column are selectively output by respective column select lines. A plurality of row and column lines are provided for the entire array 200. The row lines are selectively activated by row driver 210 in response to row address decoder 220. The column select lines are selectively activated by column driver 260 in response to column address decoder 270. Thus, a row and column address is provided for each pixel. The CMOS imager is operated by timing and control circuit 250, which controls address decoders 220 and 270 for selecting the appropriate row and column lines for pixel readout. The control circuit 250 also controls row and column driver circuitry 210 and 260, such that these apply driving voltages to the drive transistors of the selected row and column lines.

The pixel column signals, which typically include a pixel reset signal (Vᵣₛₜ) and a pixel image signal (V_{sig}) for selected pixels, are read by sample and hold circuit 261 associated with column device 260. A differential signal (Vᵣₛₜ−V_{sig}) is produced by differential amplifier 262 for each pixel which is digitized by analog to digital converter (ADC) 275. The analog to digital converter 275 supplies the digitized pixel signals to image processor 280 which forms a digital image.

Pixels of conventional image sensors, such as a CMOS imager, employ a photoconversion device as shown in FIG. 2. This photoconversion device may typically include photodiode 59 having p-region 21 and n-region 23 in p-type substrate 58. The pixel also includes a transfer transistor with associated gate 25, floating diffusion region 16, and a reset transistor with associated gate 29. Photons striking the surface of photodiode 59 generate electrons which are collected in region 23. When the transfer gate is on, the photon-generated electrons in region 23 are transferred to floating diffusion region 16 as a result of the potential difference existing between photodiode 59 and floating diffusion region 16. The charges are converted to voltage signals by a source follower transistor (not shown). Prior to charge transfer, floating diffusion region 16 is set to a predetermined low charge state by turning on the reset transistor having gate 29, which causes electrons in region 16 to flow into a voltage source connected to source/drain 17. Regions 55 are isolation regions between pixels, which could be a shallow trench isolation (STI), or an implant isolation (e.g., p-type implant separating n-type pixel regions), or a combination of both STI and implant isolation.

Conventional CMOS image sensors typically use a Bayer pattern including one red, one blue and two green colored pixels for acquiring the color information of an image. The differentiation between these pixels is achieved by using color filters for appropriate color pixels. The photo-sensing element (photodiode) for all pixels (regardless of the color) is either identical or very similar to one another. This is mainly done to simplify the processing, for example, limiting the number of masks required for fabrication and minimizing subsequent cycle time for processing the silicon. Because the absorption depths for different colors in silicon are different, placement of the photodiode junction, as well as rejection of photoelectrons from unwanted colors, could benefit from color-specific optimization. Current approaches, however, sacrifice achievable internal quantum efficiency and crosstalk performance for reduced cost in the image sensor, by using the same implants and antireflective coatings for all pixels, regardless of color. As the pixel size and the area of the photodiode shrinks, optical sensitivity is reduced. In addition, the reduction in pixel area and the larger density in a given area degrade the electrical, as well as the optical crosstalk performance. The combination of lower sensitivity and larger crosstalk results in much degradation of image quality.

### BRIEF DESCRIPTION OF THE DRAWINGS

FIG. 1 is a block diagram of a conventional imager device having a pixel array.

FIG. 2 is a cross-sectional view of a portion of a pixel in a conventional image sensor.

FIG. 3 is a cross-sectional view of a portion of a pixel, fabricated in accordance with an embodiment of the present invention.

FIG. 4a is an implant profile as a function of depth for the pixel shown in FIG. 3, when optimized for receiving blue light, in accordance with an embodiment of the present invention.

FIG. 4b is an expanded view of the implant profile shown in FIG. 4a.

FIG. 5a is an implant profile as a function of depth for the pixel shown in FIG. 3, when optimized for receiving green light, in accordance with an embodiment of the present invention.

FIG. 5b is an expanded view of the implant profile shown in FIG. 5a.

FIG. 6a is an implant profile as a function of depth for the pixel shown in FIG. 3, when optimized for receiving red light, in accordance with an embodiment of the present invention.

FIG. 6b is an expanded view of the implant profile shown in FIG. 6a.

FIG. 7 is a cross-sectional view of a Bayer pattern for adjoining green/red pixels, in accordance with an embodiment of the present invention.

FIG. 8 is a cross-sectional view of a Bayer pattern for adjoining blue/red pixels, in accordance with an embodiment of the present invention.

FIG. 9 is a cross-sectional view of a Bayer pattern for adjoining green/blue pixels, in accordance with an embodiment of the present invention.

FIG. 10 is a cross-sectional view of a Bayer pattern of adjoining blue/green pixels with a single special p-well implant, in accordance with another embodiment of the present invention.

FIG. 11 is a cross-sectional view of a portion of a pixel, similar to the pixel shown in FIG. 3, including an anti-reflective layer (ARC) disposed on top of the photodiode region, in accordance with yet another embodiment of the present invention.

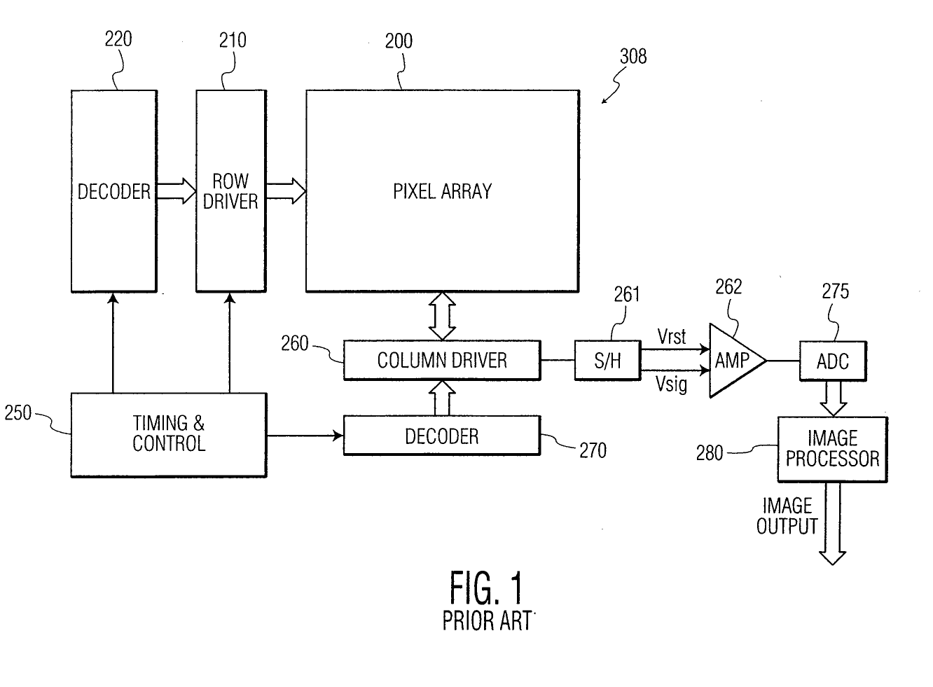

### DETAILED DESCRIPTION OF THE INVENTION

In the following detailed description, reference is made to the accompanying drawings, which form a part hereof and show by way of illustration specific embodiments in which the invention may be practiced. It is understood that other embodiments may be utilized, and that structural, logical, and electrical changes may be made without departing from the spirit and scope of the present invention.

It will be appreciated that the progression of processing steps described herein is an example of the invention. The sequence of steps, however, is not limited to that set forth herein and may be changed, as is known in the art, with the exception of steps necessarily occurring in a certain order.

The terms “wafer” and “substrate,” as used herein, are to be understood as including silicon, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “wafer” or “substrate” in the following description, previous processing steps may have been utilized to form regions, junctions, or material layers in or over the base semiconductor structure or foundation. In addition, the semiconductor need not be silicon-based, but may be based on silicon-germanium, germanium, gallium arsenide or other semiconductors.

The term “pixel,” as used herein, refers to a photo-element unit cell containing a photoconversion device for converting photons to an electrical signal. In the following description, the invention is described in relation to a CMOS imager for convenience; however, the invention has wider applicability to circuits of other types of imager devices. For example, the invention is also applicable to an output stage of a CCD imager.

As will be explained, the present invention differentiates between each color pixel and optimizes an implant method for each color separately. This allows better internal quantum efficiency, as well as reduced electrical crosstalk for each color, so that better image quality is maintained as pixel sizes are reduced.

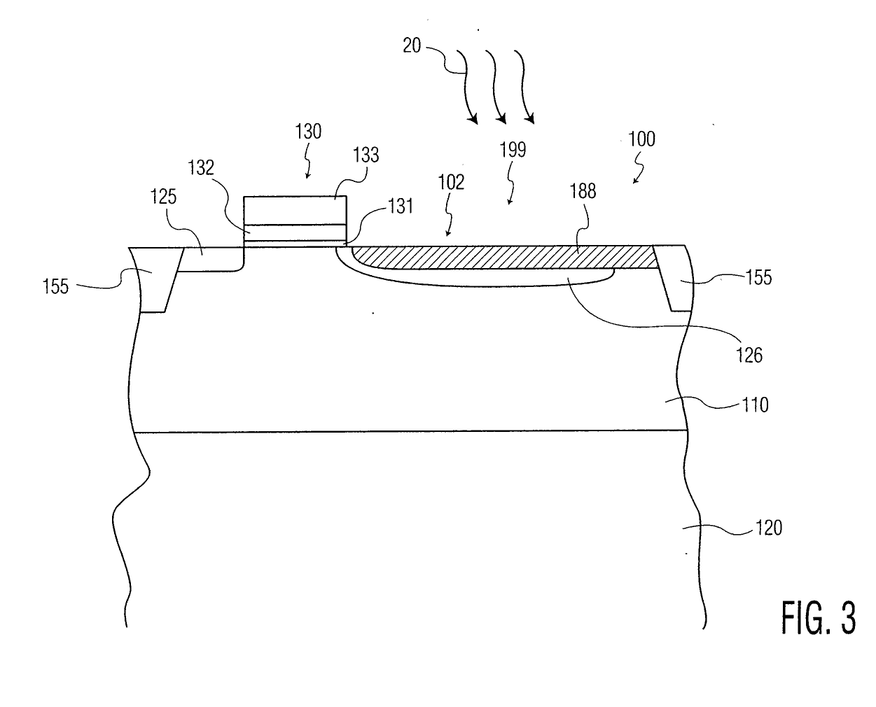

Referring now to the drawings, where like elements are designated by like reference numerals, FIG. 3 illustrates an embodiment of pixel sensor cell 100 having dopant regions 188, 126 laterally displaced from gate structure 130. The dopant regions 188, 126 form pinned buried photodiode 199.

An example of a process for fabricating the structure illustrated in FIG. 3 is described in U.S. Pat. No. 7,078,745 issued Jul. 18, 2006 to Patrick and assigned to Micron Technology, Inc. The relevant portions of the fabrication process are described below.

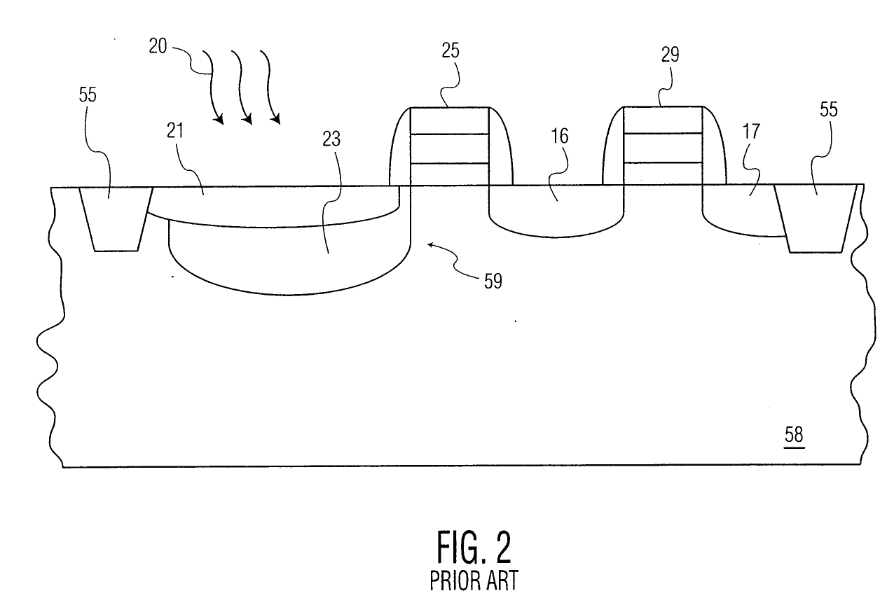

FIG. 3 illustrates substrate 110 along a cross-sectional view, which is the same view shown in FIG. 2. As an example, substrate 110 is a silicon substrate of a first conductivity type, which, for example, is p-type. However, as noted above, the invention has equal application to other semiconductor substrates. For example, the invention may be adapted to n-type substrates or substrates with buried n-wells.

FIG. 3 also illustrates isolation regions 155 which are formed within substrate 110 and are filled with a dielectric material, which may be an oxide material, for example silicon oxide, such as SiO or SiO₂, oxynitride, a nitride material such as silicon nitride, silicon carbide, a high temperature polymer, or other suitable dielectric material. As an example, isolation regions 155 are shallow trench isolation regions and the dielectric material is a high density plasma (HDP) oxide, a material which has a high ability to effectively fill narrow trenches. The shallow trench isolation regions 155 have a depth of about 1,000 to about 4,000 Angstroms, more preferably of about 2,000 Angstroms. Alternatively, the n-type photodiode regions of adjacent pixels may be isolated by p-type implantation instead of shallow trench isolation, or by a combination of trench and implant isolation.

The layer 110 of the first conductivity type, which for example is p-type, is shown disposed on a p+substrate, designated as 120. The p-type layer 110 may be a relatively thick epitaxial layer of 6-8 microns, which is grown on top of p+substrate 120. As known in the art, epitaxial layer 110 may be a boron out-diffusion from substrate 120.

Referring still to FIG. 3, the first gate oxide layer 131 of grown or deposited silicon oxide and the conductive layer 132 are sequentially formed over silicon substrate 110. The first gate oxide layer 131 and conductive layer 132 are part of a multi-layered transfer gate stack 130. The first oxide layer 131 and the conductive layer 132 may be formed by conventional deposition methods, for example, by chemical vapor deposition (CVD) or by plasma enhanced chemical vapor deposition (PECVD), among other methods.

In addition, if desired, silicide layer 133 may be formed over conductive layer 132 as part of the subsequently formed gate stack 130. Advantageously, the gate structures of all other transistors in the imager circuit may have this additionally formed silicide layer. This silicide layer may be titanium silicide, tungsten silicide, cobalt silicide, nickel silicide, molybdenum silicide, or tantalum silicide, for example.

Also shown in FIG. 3 is floating diffusion region 125. Region 125 may be an n-type doped region.

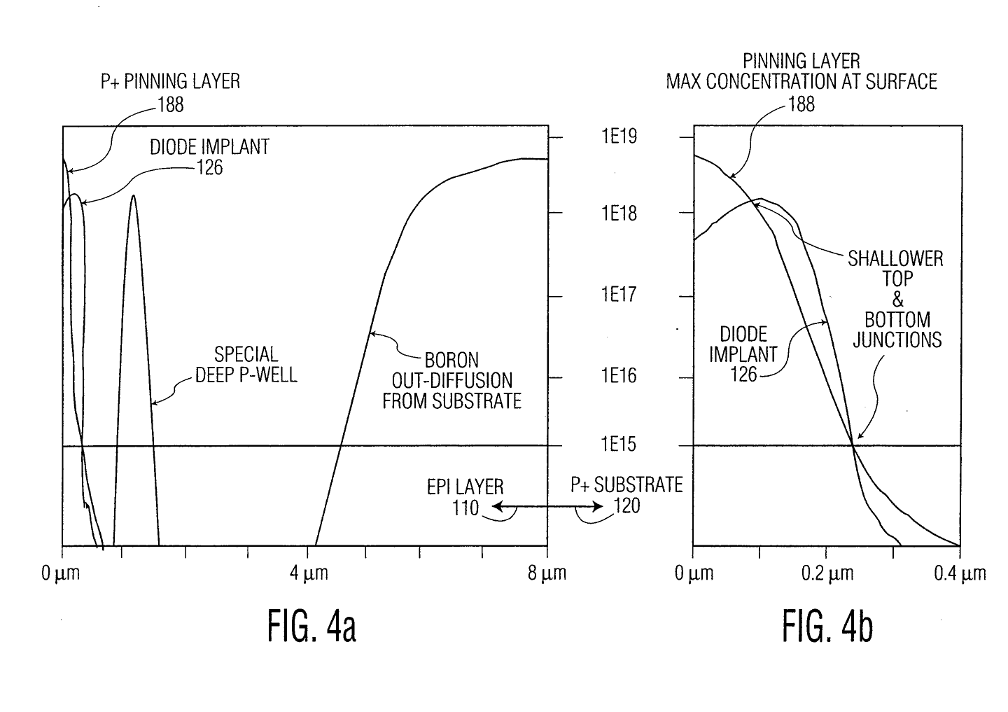

The composition of pinned buried photodiode 199 will now be described by reference to FIGS. 4a, 4b, 5a, 5b, 6a and 6b. More specifically, FIGS. 4a and 4b show examples of an implant profile for dopont regions 188 and 126 (also shown in FIG. 3).

FIG. 4b is an expanded view of FIG. 4a. The implant profile shown in FIGS. 4a and 4b assumes that pixel 100 is optimized for receiving blue light from input radiation 20 (FIG. 3).

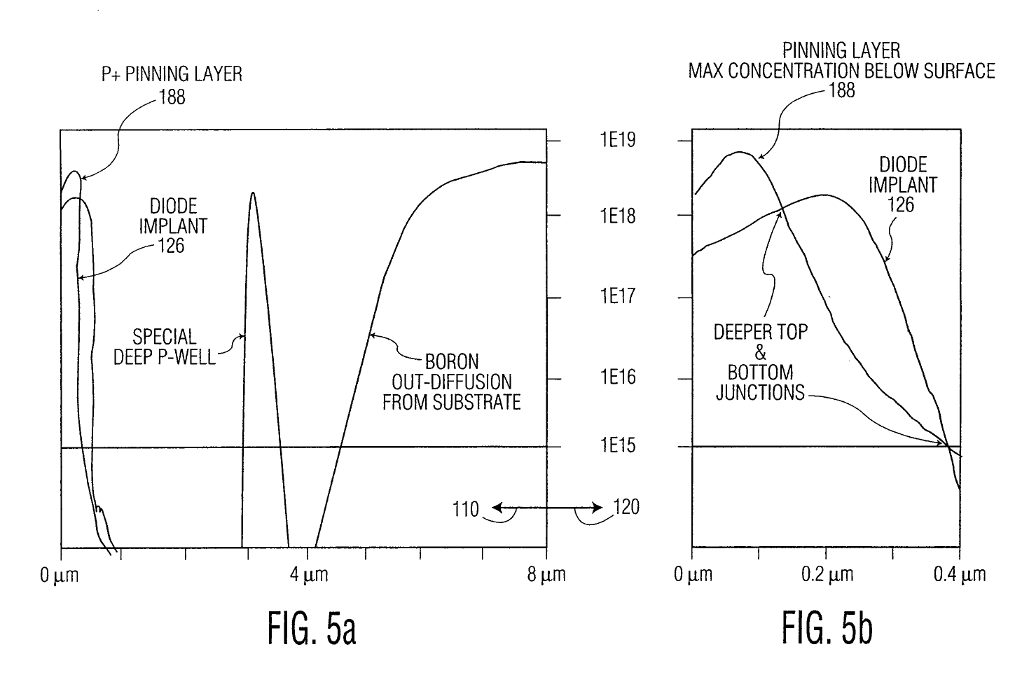

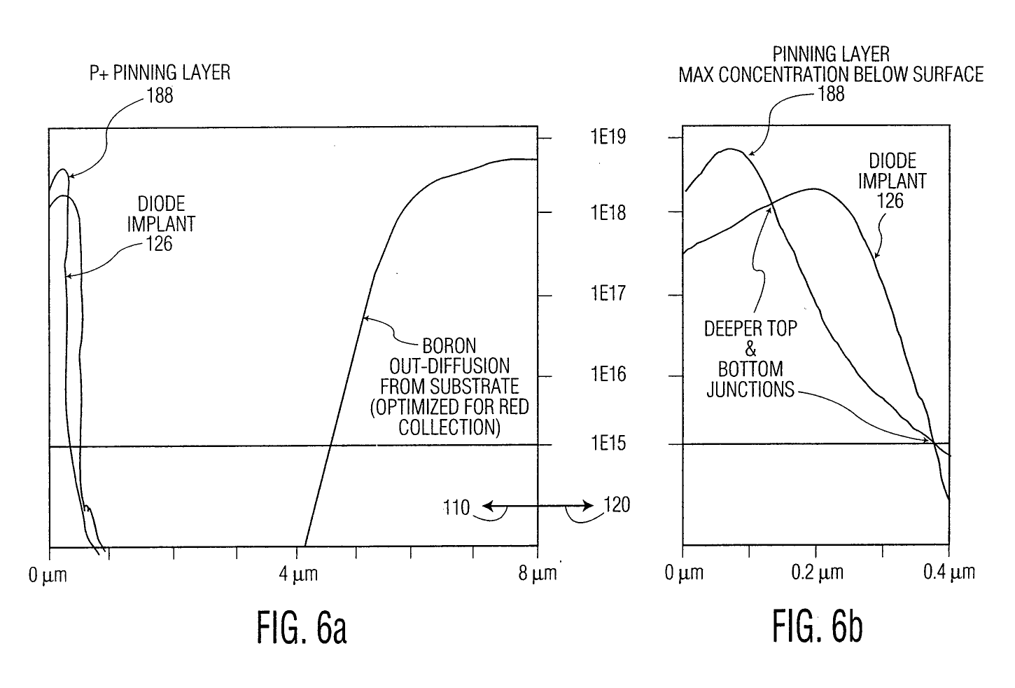

Similarly, the implant profile of FIGS. 5a and 5b assumes that pixel 100 is optimized for receiving green light from input radiation 20. Lastly, the implant profile of FIGS. 6a and 6b assumes that pixel 100 is optimized for receiving red light from input radiation 20.

As shown in FIGS. 4-6, the boron out-diffusion gradient, as it transitions from a heavily doped p+substrate 120 (FIG. 3) to a lighter doped p-type region of epitaxial layer 110, varies between approximately 5×10¹⁸ and 1×10¹⁴ atoms per cm³ from a depth of 8 microns to a depth of 4 microns, respectively. The boron out-diffusion gradient may be similar for the blue, green and red pixels, as shown in FIGS. 4a, 5a and 6a, respectively.

In accordance with an embodiment of the present invention, it may be advantageous to locate the photodiode junction within the absorption length of a specific color. For example, the absorption length of blue light (400-525 nm) ranges from 0.1 microns to 1.4 microns. As such, the photodiode junction for blue light may be located within this range. As shown in FIGS. 4a and 4b, p+pinning layer 188 and n-type diode implant layer 126 are located within 0.4 microns from the surface of blue pixel 100 (the surface, for example, being at oxide layer 131 shown in FIG. 3). Within this range, blue light may be optimally collected.

As best shown in FIG. 4b, p+pinning layer 188 has its maximum concentration at the surface (approximately 7×10¹⁸ atoms per cm³, in this example). On the other hand, n-type diode implant layer 126 has its maximum concentration below the surface, at a depth of approximately 0.1 microns. In addition, a shallower top junction (between layer 188 and layer 126) and bottom junction (between layer 126 and layer 110) are formed, as shown in FIG. 4b. By ensuring that the pinning implant peak is at the silicon/oxide interface, there is an additional electric field pushing electrons generated near the surface by short-wavelength photons away from the surface and toward the photodiode. This helps ensure that electrons generated from blue photons are collected by the photodiode, rather than recombining with holes at the surface.

With respect to the blue pixel implant profile shown in FIGS. 4a and 4b, the present invention provides a special deep p-type well implant, centered approximately at 3 times (3×) the median absorption depth of blue photons (approximately 1.2 microns). As such, the majority of the blue photons are absorbed above the special deep p-type well implant, and the generated electrons are collected by the photodiode of the blue pixel. Longer wavelength photons impinging on the blue pixel get absorbed below the special deep p-type well, such that electrons generated by longer wavelength photons are not collected by the blue pixel. These photons (electrons) are diffused to either the adjacent red pixel or the adjacent green pixel.

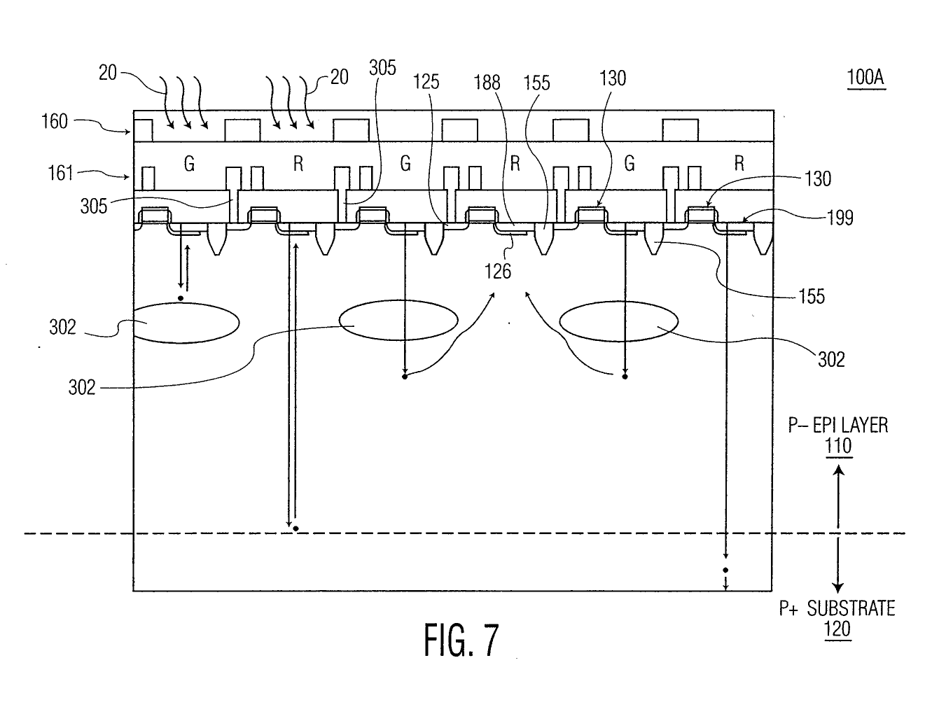

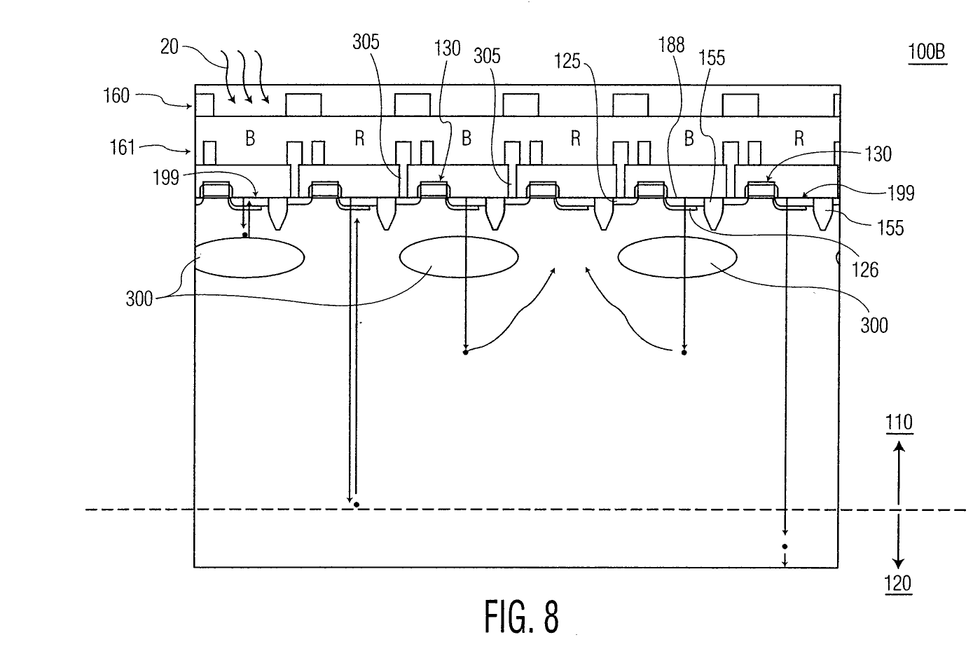

The special deep p-type well implant is shown in FIGS. 7, 8 and 9. For example, FIG. 8 shows a cross-sectional view of adjoining red/blue pixels. The special deep p-type well implant, designated as 300, is disposed underneath photodiode 199 of the blue pixel. As shown in FIG. 8, electrons generated by blue photons (with their relatively short absorption length) are collected by photodiode 199 disposed above the special deep p-type well 300. The longer absorption lengths of the red or green photons pass through the special deep p-type well 300 and generate electrons which are diffused towards the red pixel, thereby improving the collection area of the red pixel.

As an a side, FIG. 8 also shows first and second metallization layers 161 and 160, respectively. Conductive vias 305 are shown connecting first metallization layers 161 to floating diffusion regions 125.

Referring next to FIGS. 5a and 5b, there is shown an implant profile for a green pixel. The absorption length for green light (475-600 nm) ranges from 0.8 microns to 2.6 microns. In order to maintain charge transfer efficiency, however, the junction between the pinning layer and the diode implant cannot be moved that deep. It is, therefore, necessary to keep the junction/depletion region as deep as possible, while relying on diffusion and a built-in electric field outside the depletion region to move generated electrons to the depletion region boundary.

As shown in FIGS. 5a and 5b, p+pinning layer 188 and n-type diode implant layer 126 for the green pixel are located within 0.4 microns from the surface of the green pixel (for example oxide layer 131, shown in FIG. 3). As best shown in FIG. 5b, p+pinning layer 188 has its maximum concentration at a depth below the surface. The pinning layer reaches a maximum concentration of approximately 1×10¹⁹ atoms per cm³ at a depth of approximately 0.08 microns. At the surface, the pinning layer has a smaller concentration of approximately 3×10¹⁸ atoms per cm³.

The diode implant for the green pixel, designated as 126, reaches a maximum concentration of approximately 3×10¹⁸ atoms per cm³ at a depth of approximately 0.25 microns. By pushing the pinning layer implant peak concentration into the silicon substrate (thereby forming a lower p-type concentration at the silicon/oxide interface) a built-in electric field is created which directs electrons generated very close to the surface (for example, by blue photons) toward the surface, away from the n-type photodiode collection layer 126.

Still referring to FIGS. 5a and 5b, the present invention provides a special deep p-type well implant, centered approximately at a depth of 2 to 3 times (×) the median absorption depth of the green photon (approximately 2.5-4.0 microns). All longer wavelength photons (such as red photons) which get absorbed beyond this special deep p-type well implant will not be collected by this pixel. The carriers that are generated beyond the deep p-well implant (mostly photoelectrons generated by long wavelength photons) will diffuse towards the adjacent red or blue pixels. Such electrons from red light through green pixels which diffuse toward blue pixels will be re-directed towards red pixels by the special deep p-type well 300 under the blue pixels. The diffusion of carriers generated by stray red light under green pixels thus increases the effective collection area of the red pixels. This, therefore, improves the collection area for the red pixel.

As shown in FIG. 5a, the special deep p-type well of the green pixel is similar in concentration to the special deep p-type well of the blue pixel, described above. A difference, however, is the special deep p-type well of the green pixel is located at a greater depth from the surface than the depth of the deep p-type well of the blue pixel. The special deep p-type well implant, designated as 302, for the green pixel, is shown in FIG. 7. As shown, special deep p-type well 302 is disposed underneath photodiode 199 of the green pixel. The shorter wavelength photons will be absorbed by the green photodiode, disposed above special deep p-type well 302. The electrons generated at the longer absorption length of the red photon will not be collected by the green pixel. Some of the longer wavelength photons will be blocked by special deep p-type well 302 and will be deflected towards the red pixel collection area.

Referring next to FIGS. 6a and 6b, there is shown the implant profile for a red pixel. As shown, the p+pinning layer, designated as 188, and the diode implant, designated as 126, of the red pixel have the same implant profile as the implant profile of the green pixel (previously described with respect to FIGS. 5a and 5b). The absorption length for red light (575-700 nm) ranges from 2.1 to 6.0 microns. In order to maintain a charge transfer efficiency the junction between the pinning layer and the diode implant cannot be moved so deep. Consequently, it is necessary to keep the junction/depletion region as deep as possible, while relying on diffusion and the built-in electric field to move generated electrons to the depletion region boundary. A gradual transition from low to high p-type doping moving from below the depletion region toward the substrate provides an extended built-in field directing electrons generated by red photons vertically toward the photodiode. Such a gradual doping gradient can be created by boron out diffusion from a p+substrate (120) during epitaxial growth of the surface silicon epilayer (110). The thickness of the epitaxial layer may be chosen as a compromise between red collection efficiency and crosstalk caused by diffusion of electrons generated far below the surface into neighboring pixels. The inclusion of special deep p-type well implants under the blue and green pixels provides some lateral electric field to deflect deep electrons diffusing from neighboring red pixels back toward the red photodiode depletion region, thus reducing the electronic crosstalk, and allowing deeper epitaxial layers (for better red sensitivity). In other words, the boron out-diffusion profile shown in FIGS. 4a, 4b and 4c is optimized for red collection.

As described for the green pixel, pushing the concentration peak of the pinning layer 188 of the red pixel into the silicon (thereby creating a doping gradient increasing from the surface) creates a built-in electric field to direct electrons generated by shorter-wavelength photons away from the junction and back toward recombination at the surface. Here too, it is necessary to keep the junction/depletion region as deep as possible, while relying on diffusion and the built-in electric field to move generated electrons to the depletion region boundary. A gradual transition from low to high p-type doping moving from below the depletion region toward the substrate provides an extended built-in field directing electrons generated by red photons vertically toward the photodiode. Such a gradual doping gradient can be created by boron out diffusion from a p+substrate (120) during epitaxial growth of the surface silicon epilayer (110). The thickness of the epitaxial layer may be chosen as a compromise between red collection efficiency and crosstalk caused by diffusion of electrons generated far below the surface into neighboring pixels. The inclusion of special deep p-type well implants under the blue and green pixels provides some lateral electric field to deflect deep electrons diffusing from neighboring red pixels back toward the red photodiode depletion region, thus reducing the electronic crosstalk, and allowing deeper epitaxial layers (for better red sensitivity).

As also shown in FIGS. 6a and 6b, the special deep p-type well is missing from the red pixel implant profile. The deep p-type well implants, used for the blue and the green pixels, however, allow the photoelectrons generated by the long wavelength photons to diffuse towards the red pixel. This improves the collection area for the red pixel.

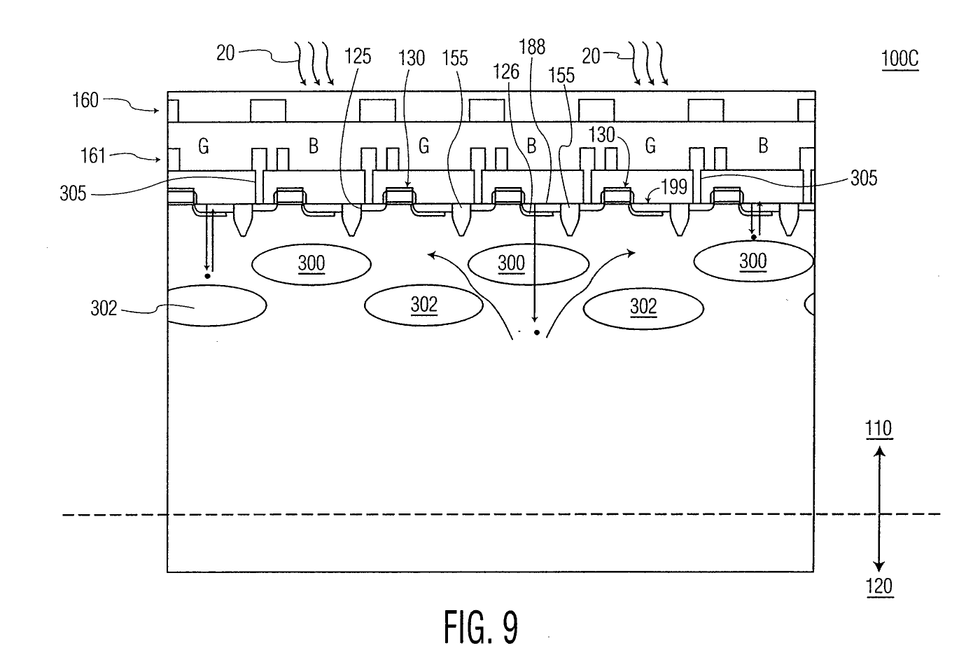

Attention is now directed toward FIGS. 7-9, which show the special deep p-type well, designated as 302, underneath the green pixel and the special deep p-type well, designated as 300, underneath the blue pixel. The substrate region underneath the red pixel, however, is free-of any special deep p-type well implant. As shown, FIG. 7 provides a cross-sectional view of a Bayer pattern (100A) for adjoining green/red pixels. Similarly, FIG. 8 shows a diagonal cut (100B) through a Bayer pattern showing adjoining blue/red pixels. Finally, FIG. 9 shows a Bayer pattern (100C) for green/blue pixels. Each of these figures schematically depicts the minimization of spectral crosstalk and optical spatial crosstalk, in which the wrong color photon is collected by a specific color pixel. These figures also show minimization of electrical crosstalk by not allowing carriers generated by long wavelength photons to be collected by the other pixels. Due to the relatively large absorption length of the green wavelength band and the practical constraints on the depth of the special p-type well implant, however, there may be some limitations in the amount of electrical crosstalk rejection between the green and the red pixels.

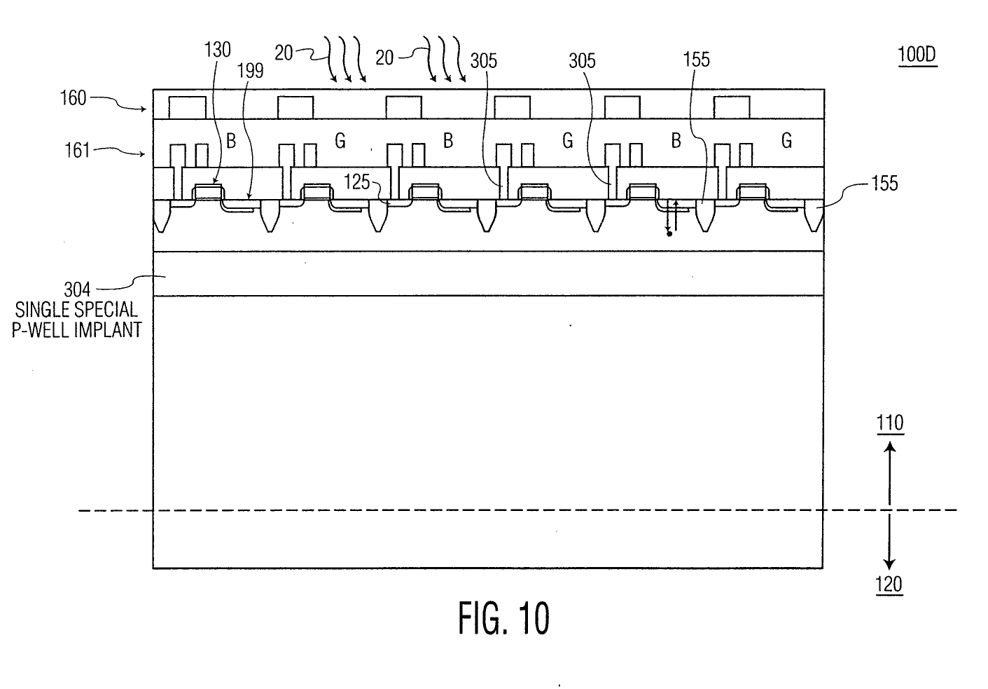

FIG. 10 shows another embodiment of the present invention, in which a single special p-type well implant, designated as 304, is placed underneath the entire region of the blue and green pixels in Bayer pattern 100D. The implant 304 selectively rejects photo-generated carriers that are from the long wavelength photons. This special p-type well implant is absent under the red pixels. Since only a single special implant is required, as shown in FIG. 10, the single implant is more cost effective than the implant profiles shown in FIGS. 7-8. It will be appreciated that in the embodiment of FIG. 10, the green special p-well implant (302 in FIG. 9) and the blue special p-well implant (300 in FIG. 9) have been replaced by a single p-well implant (304 in FIG. 10).

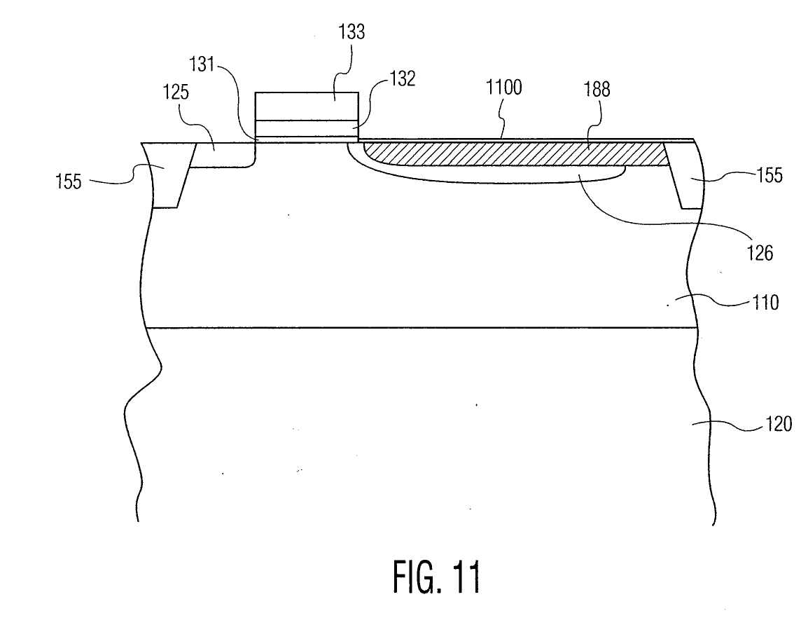

In addition to the previously described structures for improving electrical crosstalk and sensitivity, an anti-reflective coating (ARC) layer may be disposed on top of p+pinning layer 188, as shown in FIG. 11, generally designated as 1100. The ARC layer may be tuned individually for each color. Alternatively, the ARC layer may be tuned for only one pixel color, and not included for any other pixel color. For best performance, the ARC layer may have a dielectric constant which is intermediate between the silicon and the silicon dioxide. For example, the ARC layer may be comprised of silicon nitride. In addition, the ARC layer may have a thickness that is a multiple of a specific color wavelength divided by four (4).

Including ARC layer 1100 comprised of a material having a refractive index in-between silicon and silicon dioxide and of an appropriate thickness for cancellation of reflection from the silicon/silicon dioxide interface for blue light, the blue sensitivity may be maximized. Similarly, using an ARC layer comprised of a material having a refractive index in-between silicon and silicon dioxide and of an appropriate thickness for cancellation of reflection from the silicon/silicon dioxide interface for green light, the green sensitivity may be maximized.

Finally, using an ARC layer comprised of a material having a refractive index in-between silicon and silicon dioxide and of an appropriate thickness for cancellation of reflection from the silicon/silicon dioxide interface for red light, the red sensitivity may be maximized.

Because red has a longer wavelength, the ARC layer thickness for the red pixel may be of a maximum thickness. Next, the green pixel may have a smaller ARC layer thickness. The blue pixel, having the shortest wavelength, may have a minimum ARC layer thickness.

Although the invention is illustrated and described herein with reference to specific embodiments, the invention is not intended to be limited to the details shown. Rather, various modifications may be made in the details within the scope and range of equivalents of the claims and without departing from the invention. For example, the invention may be adapted to other color patterns than red/green/blue (RGB). For example, the invention may be applied to cyan/magenta/yellow (CMY) patterns. In addition, patterns other than Bayer patterns may also be used.

What is claimed:

1. A pixel sensor cell comprising:
a substrate of a first conductivity type,
a photoconversion region including a pinning layer of the first conductivity type, within the substrate, for receiving incident light of multiple colors, and a diode implant layer of a second conductivity type, disposed below the pinning layer, for accumulating photo-generated charge, and
a deep well of the first conductivity type, vertically disposed below the diode implant layer, for rejecting at least one color of the incident light.

2. The pixel sensor cell of claim 1 wherein
the deep well includes a doped region of a first dopant concentration, vertically disposed at a predetermined depth below the diode implant layer,
the diode implant layer is effective in accumulating photo-generated charge of a blue color, and
the deep well is effective in rejecting photo-generated charges of green and red colors from the diode implant layer.

3. The pixel sensor cell of claim 2 wherein
the first conductivity type is a p-type dopant concentration, and the second conductivity type is an n-type dopant concentration, and
the deep well includes a center disposed at a vertical depth approximately three times a median absorption depth of the blue color.

4. The pixel sensor cell of claim 2 wherein
the deep well has a horizontal width spanning at least a pitch width of the pixel sensor cell.

5. The pixel sensor cell of claim 2 including
an oxide layer disposed vertically above the pinning layer, wherein
the pinning layer includes a concentration level of the first conductivity type having a maximum concentration level at a junction formed between the oxide layer and the pinning layer, and
the pinning layer includes a monotonically decreasing concentration level below the junction.

6. The pixel sensor cell of claim 2 wherein
the deep well includes the p-type dopant concentration varying between about 1×10¹⁴ atoms per cm³ at ends of the deep well to about 5×10¹⁸ atoms per cm³ at a center of the deep well.

7. The pixel sensor cell of claim 1 wherein
the deep well includes a doped region of a first dopant concentration, vertically disposed at a predetermined depth below the diode implant layer,
the diode implant layer is effective in accumulating photo-generated charge of a green color, and
the deep well is effective in rejecting photo-generated charge of a red color from the diode implant layer.

8. The pixel sensor cell of claim 7 wherein
the first conductivity type is a p-type dopant concentration, and the second conductivity type is an n-type dopant concentration, and
the deep well includes a center disposed at a vertical depth approximately two to three times a median absorption depth of the green color.

9. The pixel sensor cell of claim 7 wherein
the deep well has a horizontal width spanning at least a pitch width of the pixel sensor cell.

10. The pixel sensor cell of claim 7 including
an oxide layer disposed vertically above the pinning layer, wherein
the pinning layer includes a concentration level of the first conductivity type having a maximum concentration level at a depth below a junction formed between the oxide layer and the pinning layer, and
the pinning layer includes a monotonically increasing concentration level between the junction and the depth of the maximum concentration level and a decreasing concentration level below the depth of the maximum concentration level.

11. The pixel sensor cell of claim 7 wherein
the deep well includes the p-type dopant concentration varying between about 1×10¹⁴ atoms per cm³ at ends of the deep well to about 5×10 atoms per cm³ at a center of the deep well.

12. The pixel sensor cell of claim 7 including
an adjacent pixel sensor cell including another diode implant layer effective in accumulating photo-generated charge of a red color,
wherein the adjacent pixel sensor is free of a deep well below the other diode implant layer.

13. The pixel sensor cell of claim 2 including
an adjacent pixel sensor cell including another diode implant layer effective in accumulating photo-generated charge of a red color,
wherein the adjacent pixel sensor is free of a deep well below the other diode implant layer.

14. An imager having a pattern of red, blue and green color filters disposed above an array of pixels in a substrate, the imager comprising:
a blue pixel implant profile for each pixel disposed below a blue color filter,
a green pixel implant profile for each pixel disposed below a green color filter, and
a red pixel implant profile for each pixel disposed below a red color filter,
wherein the blue pixel implant profile includes a first deep well disposed vertically below a first pinning layer, the first pinning layer disposed at a surface of the substrate,
the green pixel implant profile includes a second deep well disposed vertically below a second pinning layer, the second pinning layer disposed at the surface of the substrate, and
the second deep well is disposed vertically lower than the first deep well.

15. The imager of claim 14 wherein
the red pixel implant profile includes a third pinning layer disposed vertically at the surface of the substrate, and
the red pixel implant profile is free-of a deep well disposed vertically below the third pinning layer.

16. The imager of claim 14 wherein
the first deep well is centered approximately at a vertical depth of three times a median absorption depth of a blue photon, and
the second deep well is centered approximately at a vertical depth of two to three times a median absorption depth of a green photon.

17. The imager of claim 14 wherein
the first pinning layer has a maximum concentration at the surface of the substrate, and
the second pinning layer has a maximum concentration below the surface of the substrate.

18. The imager of claim 14 wherein
the substrate is of a p-type conductivity,
the first and second pinning layers are of p+dopants, and the first and second deep wells are of p+dopants.

19. The imager of claim 14 wherein
the substrate includes an epitaxial layer of p-type conductivity disposed on top of a p+dopant layer.

20. The imager of claim 14 wherein
the first deep well is configured to block green and red photons from being absorbed vertically above the first deep well, and
the second deep well is configured to block red photons from being absorbed vertically above the second deep well.

21. A method for operating pixel cells in a pixel array of an imaging device, the method comprising the steps of:
converting incident light, by a first pinning layer of a first pixel cell, into electrons for absorption of blue photons by a first diode implant;
converting incident light, by a second pinning layer of a second pixel cell, into electrons for absorption of green photons by a second diode implant;
blocking green and red photons from being absorbed by the first diode implant by a first deep well disposed vertically below the first diode implant; and
blocking red photons from being absorbed by the second diode implant by a second deep well disposed vertically below the second diode implant.

22. The method of claim 21 including the steps of:
converting incident light, by a third pinning layer of a third pixel cell, into electrons for absorption of red photons by a third diode implant; and
absorbing red photons, which are blocked from being absorbed by the first and second deep wells, by the third diode implant.

23. The method of claim 22 wherein
the first, second and third pixel cells form part of a pattern of one red, one blue and two green colored pixels.

24. The method of claim 21 including the step of:
maximizing a p+dopant concentration level at a surface level of the first pinning layer to form an electric field for absorbing the blue photons by the first diode implant.

25. The method of claim 21 including the step of:
maximizing a p+dopant concentration level below a surface level of the second pinning layer to form an electric field which pushes away the blue photons from the surface level of the second pinning diode.
